(19) United States
(12) Patent Application Publication
(10) Pub. No.: US 2010/0163185 A1
(43) Pub. Date: Jul. 1, 2010

(54) Vacuum processing apparatus

(76) Inventors: Michiaki Kobayashi, Kudamatsu (JP); Tsutomu Nakamura, Hikari (JP); Koji Okuda, Shunan (JP); Masakazu Isozaki, Shunan (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/379,642

(22) Filed: Feb. 26, 2009

(30) Foreign Application Priority Data
Dec. 26, 2008 (JP) 2008-331823

(51) Int. Cl. H01L 21/3065

(52) U.S. Cl. 156/345.31

(57) ABSTRACT

A vacuum processing apparatus which includes a vacuum vessel having a processing chamber provided therein into which a processing gas is supplied to form a plasma and which processes a wafer located in the processing chamber, and a vacuum transfer vessel having a vacuumed transfer chamber coupled with the vacuum vessel provided therein into which the wafer is transferred. A resin-made film having a plasma resistance is bonded onto a surface of a lid of the vacuum transfer vessel on the side of the transfer chamber.

### BACKGROUND OF THE INVENTION

The present invention relates to vacuum processing apparatuses which include a vacuum vessel having an internal chamber for processing a substrate-like specimen such as a semiconductor wafer in an atmosphere of plasma generated within the vacuumed vacuum chamber, and more particularly, to a vacuum processing apparatus which also includes a vacuum transfer vessel having an internal transfer chamber connected with the vacuum vessel so that the specimen can be transferred through depressurized internal transfer chamber.

### SUMMARY OF THE INVENTION

In processing a semiconductor wafer, for example, during manufacture of a semiconductor device using the aforementioned vacuum processing apparatus, it is demanded to reduce contamination caused by fine particles, so called a submicron level of foreign matter. For example, when a plasma is generated and then etching is carried out, various sorts of compounds or reactions caused by interactions between the plasma and a material in the surface of a wafer are formed in the plasma.

When such products are deposited and gradually built up on the surface of the semiconductor wafer, the built-up products form a mask and the wafer surface has such a location that no intended action is applied thereto due to the mask, thus disabling accurate formation of an electric circuit. This disadvantageously results in a bad manufacturing yield.

Such foreign matter is generated by various types of causes. For example, there may occur, in some cases, such a case that fine particles or the like are peeled off from the internal wall surface of vacuum vessel of a semiconductor manufacturing apparatus during transferring the wafer through the transfer chamber of the apparatus and fall on the wafer to form foreign matter. Though various types of materials are used for the vacuum processing apparatus, an aluminum-based material is often employed as the member material of the vacuum vessel from the viewpoint of its features including easy treatment and light weight. In the case of the aluminum-based material, however, a highly reactive gas is introduced into the vacuum vessel for treatment of the specimen. Thus, the gas disadvantageously reacts with the aluminum-based material, which undesirably leads to corrosion of the vacuum vessel or to generation of foreign matter.

In order to suppress such corrosion or reaction, it is general to subject the surface of the member of the vacuum vessel to anodic oxidation. In some cases, however, an oxidized member film is formed on the anodically-oxidized surface of the member, the film usually has a porous surface, and a groove called a microcrack is formed in the film surface. Such a crack is considered to cause peeling off of the film or separation thereof into pieces, possibly forming foreign matter.

In order to solve such a problem by covering the aforementioned porous part or microcrack, such a surface treatment method as to deposit a resin thereon has so far been employed. As such prior art techniques, JP-A-2004-260159 (Patent Document 1) and JP-A-2004-292887 (Patent Document 2) are disclosed and known.

The Patent Document 1 discloses a plasma processing apparatus in which a substrate to be treated in a treatment container is surrounded by a ring member, and electrodes are provided in the ring member, wherein a film having a barrier function of less corrosion is formed on the surface of the ring member. In the disclosed Patent Document, in particular, this film includes a film formed by anodizing the surface of the ring member and a film of a resin covering the upper surface of the anodized film such as a PTFE (polytetrafluoroethylene) layer.

Also disclosed in the Patent Document 2 is a plasma processing apparatus in which the surface of an aluminum member used within a vessel of the plasma processing apparatus is anodized to form a film thereon. Also disclosed in the same Patent Document is the fact that the anodized surface of the obtained film is subjected to sealing treatment.

In these years, a semiconductor device is more increasingly miniaturized and even finer foreign matter becomes problematic. In a prior art surface treatment method, in this way, many particles of fine foreign matter still remain on the surface of the member, and the prior art method cannot sufficiently cope with suppression of formation of finer foreign matter dust particles.

In the above prior art technique, consideration is not paid sufficiently to the above respect, thus arising a problem.

For example, with regard to such a member, when a specimen is transferred in a plurality of chambers of the apparatus having predetermined vacuum level pressures kept therein, it is required to adjust a pressure in a vacuum vessel for the purpose of reducing a pressure difference between the chambers. Upon the pressure adjustment, a fluidic force of an introduced gas such as a nitrogen gas and an external force accompanied by an increase or decrease in the pressure of the chamber applied to the surfaces of the members forming the vacuum chamber. It is known by the inventors, et al. of the present application that such an external force acts on such a multiplicity of deposited particles as mentioned above, and some of the particles are peeled off and fall to form foreign matter.

More specifically, as mentioned above, members which are obtained, for example, by anodizing the surface of an aluminum member using a sulfuric acid solution or by anodic oxide coating (which will be referred to merely as the almite treatment, hereinafter) to form an anodic oxide coating or film and by forming a film made of PTFE (polytetrafluoroethylene) thereon (which will be referred to merely as the PTFE treatment, hereinafter), are employed as members forming the vacuum processing apparatus. FIG. 6 shows an observed result of the surface of a film obtained when the surface of a film obtained by subjecting an aluminum-made substrate to the almite treatment using a sulfuric acid solution is further subjected to the PTFE treatment, with respect to a vacuum chamber member in such a semiconductor manufacturing apparatus.

As shown in this drawing, the surface of the film subjected to the aforementioned treatments for the purpose of suppressing formation of foreign matter has such a structural state that fine particles are distributed to be irregularly deposited in the form of many layers. For this reason, it has been found that such fine particles may undesirably cause formation of foreign matter.

Further, since a difference between a pressure of a predetermined vacuum level inside the vacuum vessel and an atmospheric pressure outside the vacuum vessel is applied as a load to a member having a large surface area, the members of the vacuum vessel are deformed to increase a damage for an anodized film on the surface of the member and to undesirably form foreign matter from peel-off or damage of the anodized film. The formation of such foreign matter causes reduction of a yield of processing a specimen such as a wafer, which leads to a decreased productivity. Such a problem is not considered in the aforementioned prior arts.

It is therefore an object of the present invention to provide a vacuum processing apparatus which can suppress formation of foreign matter in the interior of a vacuum vessel with an improved productivity.

The above object is attained by providing a vacuum processing apparatus which includes a vacuum vessel in which a processing chamber is provided to have a processing gas supplied thereinto, and to generate a plasma therein and to process a wafer located in the processing chamber, and which also includes a vacuum transfer vessel in which a transfer chamber is provided to be coupled with the vacuum chamber to transfer the wafer in the interior of the vacuumed transfer chamber. In the vacuum processing apparatus, a resin film having a plasma resistance property is bonded on the surface of a lid of the vacuum transfer vessel on the side of the transfer chamber.

Further, the above object is attained by the lid which is a plate-like member supported to be connected at its outer periphery end with the main body of the vacuum transfer vessel. The above object is also attained by the film which is bonded onto the surface of the central part of the lid provided on the side of the transfer chamber.

The above object is also attained by the film which is made of a resin containing polyimide or polyester as its main component. The object is further attained by the lid which is connected to a grounding potential and by the film which is made electrically conductive with the lid.

The object is further attained by a plurality of through holes and which are arranged at intervals of a predetermined spacing and which are passed through the film between the surface thereof on the transfer chamber and the bonding surface to the lid. The object is also attained by the film having a plurality of grooves. The grooves are formed in the bonding surface before the film is bonded onto the lid, and are extended from one end of the film to the other end thereof, with the inner surfaces of the grooves being tightly contacted with the surface of the lid after the film is bonded onto the lid.

Other objects, features and advantages of the invention will become apparent from the following description of the embodiments of the invention taken in conjunction with the accompanying drawings.

### BRIEF DESCRIPTION OF THE DRAWINGS

FIG. 1 schematically shows, in a model form, a top view of an arrangement of a vacuum processing apparatus in accordance with the present invention;

FIG. 2 schematically shows, in a model form, a vertical cross-sectional view of structures of a vacuum transfer vessel, lock chamber, a vacuum processing unit in the embodiment of FIG. 1;

FIG. 3 is a bottom view of an inside surface of a lid of the vacuum transfer vessel in the embodiment of FIG. 2;

FIG. 4 is an enlarged bottom view of a part of a film on a rear surface of the lid shown in FIG. 3;

FIG. 5A is a bottom view of another film when bonded to the lid shown in FIG. 3;

FIG. 5B is a vertical cross-sectional view of the film of FIG. 5A; and

FIG. 6 shows an observed result of a surface of a film obtained by subjecting an aluminum-made substrate to anodic oxide coating or almite treatment and then to PTFE treatment in a prior art.

### DESCRIPTION OF THE EMBODIMENTS

Embodiments of the present invention will be explained with reference to the accompanying drawings.

### Embodiment 1

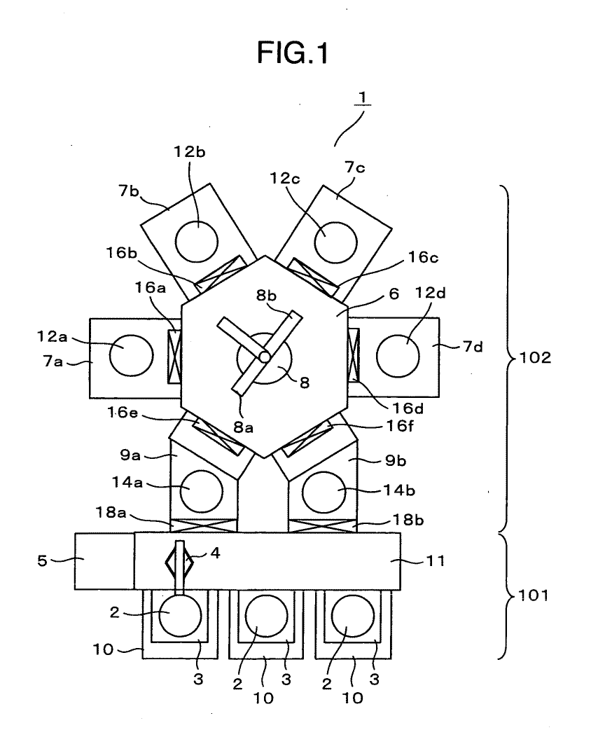

The embodiments of the present invention will be explained by referring to FIGS. 1 to 5.

FIG. 1 schematically shows, in a model form, a top view of an arrangement of a vacuum processing apparatus in accordance with the present invention.

A vacuum processing apparatus 1 shown in FIG. 1 roughly includes an atmosphere-side processing section 101 and a vacuum-side processing section 102 in a room where the apparatus is installed. In the atmosphere-side processing section 101, cassette bases 10 each having a cassette 3 accommodating a specimen such as a wafer 2 therein, the cassette 3 being transferred along a cassette transfer passage, are provided on the side of the passage. The vacuum-side processing section 102 includes a plurality of vacuum processing units 7a, 7b, 7c, 7d for processing a plurality of the wafers 2 accommodated in the cassettes 3 using a plasma in the vacuumed processing chamber; a vacuumed transfer vessel 6 which is coupled with the vacuum processing units 7a, 7b, 7c, 7d and in which the wafers 2 are transferred in the vacuumed interior of the vessel; and lock chambers 9a, 9b coupled with the vacuum transfer vessel 6 and also with the atmosphere-side processing section 101 for switching between the atmosphere and a vacuum pressure to transfer the wafers 2 into or out of the chambers.

Each of the vacuum processing units 7a, 7b, 7c, 7d and the lock chambers 9a, 9b is provided with a vacuum vessel which has a processing chamber therein kept at an internal pressure vacuumed down to a level equivalent to the internal pressure of the vacuum transfer vessel 6. Specimen bases 12a, 12b, 12c, 12d are provided in the respective processing chambers of the vacuum processing units 7a, 7b, 7c, 7d to have mounting surfaces on which the wafers 2 fed into the respective processing chambers are to be mounted. The wafers 2 are processed using plasmas generated in the respective processing chambers under a condition that the wafers 2 are fixedly mounted on the specimen bases 12a, 12b, 12c, 12d.

Specimen bases 14a, 14b for mounting the wafers 2 thereon before or after the processing are mounted even in the lock chambers 9a, 9b. Under a condition that the wafers 2 are mounted on the upper surfaces of the specimen bases 14a, 14b, pressures in the lock chambers 9a, 9b are adjusted at levels between the atmosphere and a predetermined vacuum pressure.

Mounted within the vacuum transfer vessel 6 is a vacuum transfer robot 8 as a means for transferring the wafers 2 between the specimen bases 12a, 12b, 12c, 12d and the specimen bases 14a, 14b. The vacuum transfer robot 8 has an axis in the vicinity of a center of the vacuumable transfer chamber as viewed from its top, and two robot arms 8a, 8b are provided to be rotated around the axis of the vacuum transfer robot. Each of the robot arms carries the wafer 2 on its upper surface and transfers the wafer between the robot arm and the associated specimen base.

Also provided between the vacuum processing units 7a, 7b, 7c, 7d, and the lock chambers 9a, 9b and the vacuum transfer vessel 6 are gates which separate the vacuum processing units from the associated internal chambers and through associated openings of which the wafers 2 are transferred, and gate units 16a, 16b, 16c, 16d, 16e, 16f having gate valves for opening or closing the associated gates.

The atmosphere-side processing section 101 includes a plurality of the cassette bases 10 provided in the front of the atmosphere-side processing section for mounting the cassettes 3 capable of accommodating a plurality of wafers on their upper surfaces in the atmosphere, an atmosphere transfer vessel 11 having the wafers to be transferred therein, an atmosphere transfer means 4 located within the atmosphere transfer vessel 11 including the robot arms arranged to be vertically and horizontally movable and to be inserted into the associated cassettes 3 or be extracted therefrom for wafer transfer, and a positioning device 5 for positioning the wafers 2.

The lock chambers 9a, 9b are connected with the atmosphere transfer vessel 11 so that their internal chambers are in communication with each other. The lock chambers 9a, 9b are arranged so that the internal pressures of the lock chambers 9a, 9b can be changed to levels between a pressure equal to the atmosphere (atmospheric pressure) outside of the apparatus and a pressure equal to the internal pressure of the vacuum transfer vessel 6. Gate units 18a, 18b having gate valves for tightly sealing gates connected therebetween are provided between the lock chambers 9a, 9b and the atmosphere transfer vessel 11, so that the lock chambers can communicate with the atmosphere transfer vessel via the gates within the gate units 18a, 18b and the gates can be opened or closed by driving the gate valves.

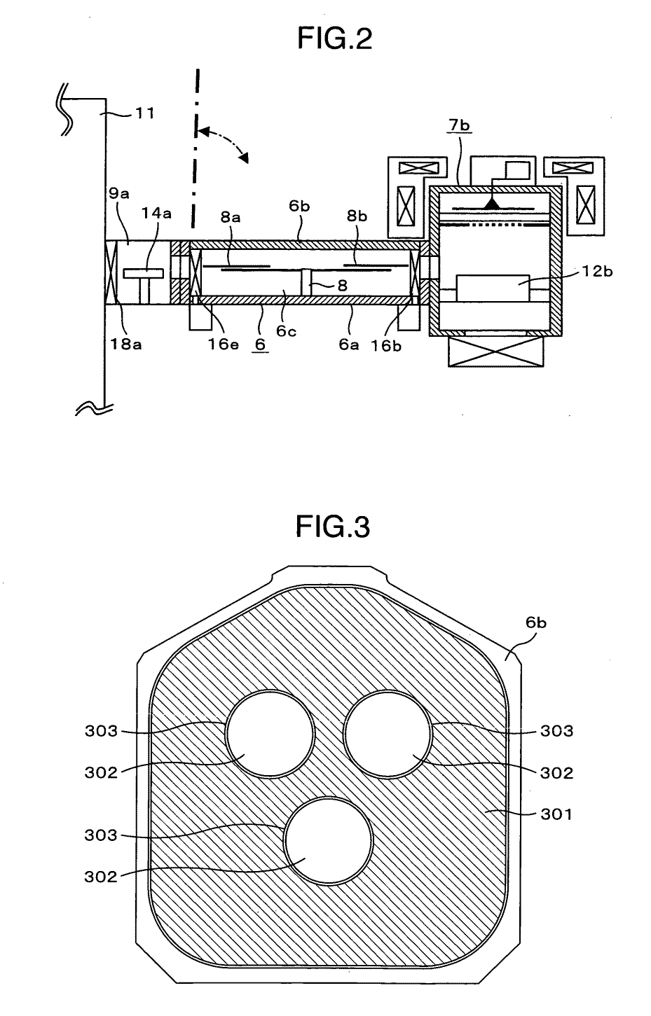

By referring to FIG. 2, the arrangement of the vacuum-side processing section 102 will be explained in detail. FIG. 2 schematically shows, in a model form, a vertical cross-sectional view of structures of the vacuum transfer vessel 6, lock chamber 9a, vacuum-side gate unit 16e, and atmosphere-side gate unit 18a, and also of structures of the vacuum processing unit 7b and vacuum-side gate unit 16b.

The vacuum transfer vessel 6 is provided with a main body 6a of the vacuum transfer vessel, a lid 6b, and a vacuum transfer robot 8. As shown in FIG. 1, the vacuum transfer vessel 6 in the present embodiment is a metal-made vacuum vessel of a polygonal shape (hexagonal shape in the illustrated example) as viewed from top, side walls of the vacuum transfer vessel 6 corresponding to the sides of the polygonal shape are coupled with the vacuum processing unit 7b and the lock chamber 9a, and the gate units 16b, 16e are located between the vacuum processing unit and lock chamber and the vacuum transfer vessel main body 6a and a vacuumed transfer chamber 6c as a transfer space through which the wafer 2 is transferred.

The other end of the lock chamber 9a opposed to one end thereof coupled with the vacuum transfer vessel 6 is coupled with the atmosphere transfer vessel 11, and the gate unit 18a for separating the lock chamber from the atmosphere transfer vessel is provided between the lock chamber and the vacuum transfer vessel.

An example of a flow of the wafer 2 in the vacuum processing apparatus 1 of the present embodiment will be explained by referring to FIGS. 1 and 2. A wafer 2 accommodated in the cassette 3 placed on the cassette base 10 is extracted from the cassette 3 by the atmosphere transfer means 4, set at its predetermined position by the positioning device 5, transferred to any of the lock chambers 9a, 9b having a pressure adjusted to the atmospheric pressure, and then placed on the mounting surface of any of the specimen bases 14a, 14b. In this example, explanation will be made as to an example when the wafer is transferred onto the specimen base 14a of the lock chamber 9a.

Thereafter, the gate valve separates the lock chamber from the atmosphere transfer vessel 11 so as to close a communication between the lock chamber and the atmosphere transfer vessel 11 through operation of the gate unit 18a, and the gate unit 16e provided at the other end thereof is tightly closed. As a result, the lock chamber is tightly sealed. The lock chamber 9a has an evacuating means such as a vacuum pump for evacuating the lock chamber. Thus the lock chamber 9a is vacuumed by the evacuating means down to a pressure equal to the internal pressure of the vacuum transfer vessel 6 kept at a predetermined vacuum level. Thereafter, the vacuum-side gate unit 16e is opened, any of the robot arms 8a, 8b of the vacuum transfer robot 8 located within the vacuum transfer vessel 6 enters the lock chamber 9a, takes out the wafer 2 from the specimen base 14a, passes through the gate of the gate unit 16b, and places the wafer on the specimen base 12b located in the processing chamber of the vacuum processing unit 7b.

The wafer 2 processed under predetermined conditions within the processing chamber of the vacuum processing unit 7b is transferred from the specimen base 12b to any of the lock chambers 9a, 9b by the vacuum transfer robot 8 again through the gate unit 16b, and then placed on any of the specimen bases 14a, 14b. This example is explained when the wafer is returned to the lock chamber 9a.

Thereafter, the pressure of the inside space of the lock chamber 9a having the wafer 2 accommodated therein is increased up to the atmospheric pressure by a purging means, the gate unit 18a is released, the wafer 2 is transferred by the atmosphere transfer means 4 from the specimen base 14b within the lock chamber 9a and then returned to the initial position of the original cassette 3.

As shown by a dashed line in the drawing, the lid 6b is arranged to be opened upwardly with respect to a hinge provided at a front or rear side of the vacuum transfer vessel 6. With such a structure, after the internal pressure of the transfer chamber of the vacuum transfer vessel 6 is returned to the atmospheric pressure, a user can conduct maintenance works including inspection and component exchange by opening the lid with the center of the hinge.

In the present embodiment, since a resin-made film having a chemical resistance for reducing an interaction on the inside wall surface of the lid 6b as one of members of the vacuum transfer vessel 6 is provided on the inside wall surface of the lid which highly undergoes a load based on a difference between the predetermined vacuum pressure and the atmospheric pressure, this can suppress generation of foreign matter during transfer of the wafer 2. In the present embodiment, in particular, the resin-made film is bonded onto the inside wall surface of the lid.

By referring to FIG. 3, explanation will then be made as to the location of the film capable of suppressing formation of foreign matter. FIG. 3 shows a bottom view (inside or rear side) of the lid 6b of the vacuum transfer vessel in the embodiment of FIG. 2. In the present embodiment, a film 301 containing polyimide or polyester as its main component is bonded onto the rear surface of the lid 6b at its center.

The lid 6b in the present embodiment is a disc-shaped member as an upper lid of the vacuum transfer vessel 6, and the lid is made of a material containing aluminum or its alloy as its main component. A plurality of circular windows 302 are located at the central part of the rear surface of the film. The vacuum transfer vessel 6 has a nearly hexagonal shape when viewed from top, the lid 6b is arranged to be mounted at its outer peripheral edge on the upper end of the hexagonal side wall of the vacuum transfer vessel and to tightly seal the interior of the vacuum transfer vessel. In other words, the outer periphery of the lid 6b is connected to the upper end of the side wall of the vacuum transfer vessel main body 6a so that the inner peripheral side (center side) of the main body is supported to be sealed.

The film 301 is bonded onto the inside of the outer peripheral end of the vacuum transfer vessel main body 6a as its connection location so as to coincide with the shape of the polygonal shape lid 6b. The planar shape of the film has a polygonal shape having corners rounded so as to be matched with the corners of the polygonal shape of the lid 6b. The film 301 has openings 303 circular in this example so as to coincide with the shape of the windows 302 of the lid 6b. The film 301 is bonded onto the lid so that the inside wall surface of the lid member 6b is made to coincide with the openings 303 and the windows 302, and the film 301 is not extruded into the windows 302. In this connection, part of the rear surface of the lid 6b at least bonded and covered with the film 301 is not only formed with the anodized film but also not subjected to treatment of covering the film with a resin such as PTFE.

The inner peripheral edges of the openings 303 are formed to coincide with the inner peripheral edges of the circular windows 302. And when the film 301 is bonded onto the lid, the surface area of extrusions of the outer peripheries of the windows 302 in the lid 6b as a member made of aluminum or its alloy as its main component into insides of the openings 303 to be exposed within the transfer chamber, is minimized. This suppresses foreign matter from being formed by an interaction between the extrusions and the reactive gas within the transfer chamber.

The film 301 of the present embodiment can be expanded or contracted according to the deformation of the lid 6b caused by a difference between pressures inside and outside of the lid made of a resin as a main component. To this end, the film 301 is tightly bonded onto the entire front and rear surfaces of the lid 6b according to its shape. Even when the front surface of the lid 6b is displaced or deformed, the bonded surface is suppressed from being peeled off. As a result, the reactive gas is prevented from entering a gap between the lid 6b and the film 301, and therefore an interaction between the lid 6b and the gas is suppressed. This leads to avoidance of generation of foreign matter. The film 301 is made of, as its main component, such a material having a high plasma resistance as to hardly cause a reaction with a highly reactive substance in a plasma such as polyethylene or polyester. Even this enables suppression of generation of foreign matter.

The openings 303 are formed to be located nearly at the central part of the film 301 so that the openings 303 accommodate the entire windows 302 located nearly at the central part of the lid after the film is bonded to the lid. Since the windows 302 of the lid 6b are covered at the central part with the associated openings 303 of the film as far as the outer peripheral sides of the windows 302, consideration is paid to the deformation of the lid 6b to suppress peel off with improved reliability and operational life.

Further, the film 301 of the present embodiment is bonded onto the lid 6b made of a conductive metal (such as aluminum or an aluminum alloy as its main component). However, in order to suppress charged particles within the transfer chamber caused by charging of the film 301 or dust tending to be charged with static electricity from being adsorbed on the film 301, the film may be formed by evenly mixing the conductive material. The vacuum transfer vessel 6 or the vacuum vessels of the vacuum processing units 7a, 7b, 7c, 7d and the lock chambers 9a, 9b are usually made of conductive metals, and electrically grounded. The vacuum transfer vessel 6 connected to these vessels are also grounded at a substantially constant potential (0V).

Since the bonded film 301, which has the aforementioned conductive property, is also electrically connected with the lid 6b and grounded at the ground potential, particles or dust possibly causing formation of foreign matter can be suppressed from being deposited.

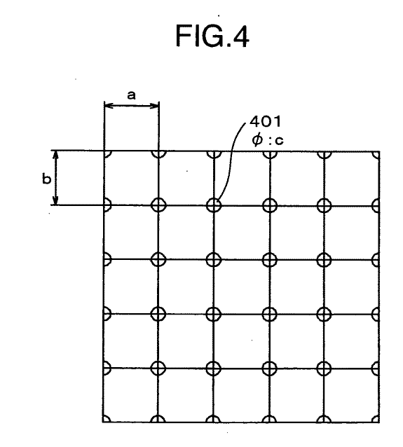

FIG. 4 shows an enlarged bottom view of a part of the film 301 provided on the rear surface of the lid 6b. As illustrated, a plurality of through holes passed through the film 301 of the present embodiment between its upper and lower surfaces (front and rear surfaces) may be formed in the film 301.

The film 301 of the present embodiment is deformed by a deflection of the lid 6b caused by a difference between a vacuum pressure and the atmospheric pressure. An amount of such deformation becomes largest at its central part. In the prior art, as the deformation is larger, a crack in the film formed by anodizing becomes larger or a new crack takes place. As a result, small-diametered particles deposited on the front surface of the film by processing of a defective or peeled-off part of the film or by hole sealing are disadvantageously liberated to form foreign matter.

In the present embodiment, the film 301 is designed to cover at least 70% of the full surface area of the rear surface of the lid 6b facing the transfer chamber, with the most deformed point being used as a center. When a gap takes place between the contacted surfaces of the film 301 and the lid 6b and a gas enters the gap, a reduction in the internal pressure of the transfer chamber causes the gap between the film 301 and the rear surface of the lid 6b to become large, which possibly leads to the fact that the contact between the film and the lid is destroyed or the pressure is varied.

In the present embodiment, in order to suppress generation of such a gap or air bubbles, through holes 401 are formed in the film 301 at intervals of a predetermined spacing. With such array of these through holes 401, when the film 301 is pushed against the rear surface of the lid 6b to cause the film 301 to be bonded onto the lid rear surface, a gap or air bubble is generated between the film and the lid. Even in this case, such an air bubble can be easily removed by pushing the film 301 from the upper side of an air bubble generation location and by pushingly shifting the air bubble location as far as the position of the through holes 401.

Even when a reduction in the internal pressure of the transfer chamber causes the volume of such air bubble to expand or the surface area thereof to be increased, arrival of the air bubble at the through holes 401 arranged at intervals of a suitable spacing results in that a gas in the air bubble to leak into the transfer chamber from the through holes 401, thus shrinking the air bubble. Each of the through holes 401 has a cylindrical or truncated cone shape. Thus, when the film 301 is deformed according to a displacement of the corners of the lid 6b having the film 301 bonded thereonto, a stress concentration or deformation bias is reduced. To this end, the bonding of the inner peripheral edge of each through hole 401 of the film 301 is designed to be less broken, and even such breakage involved by the arrival of such air bubble causes the deformation of the film 301 to produce an internal force so as to quickly achieve rebonding.

In the present embodiment, a spacing between the through holes 401 is set at a value between 5 and 50 mm and when the through hole 401 has a cylindrical shape, the diameter φ of the hole is set at a value between 10 and 100 μm.

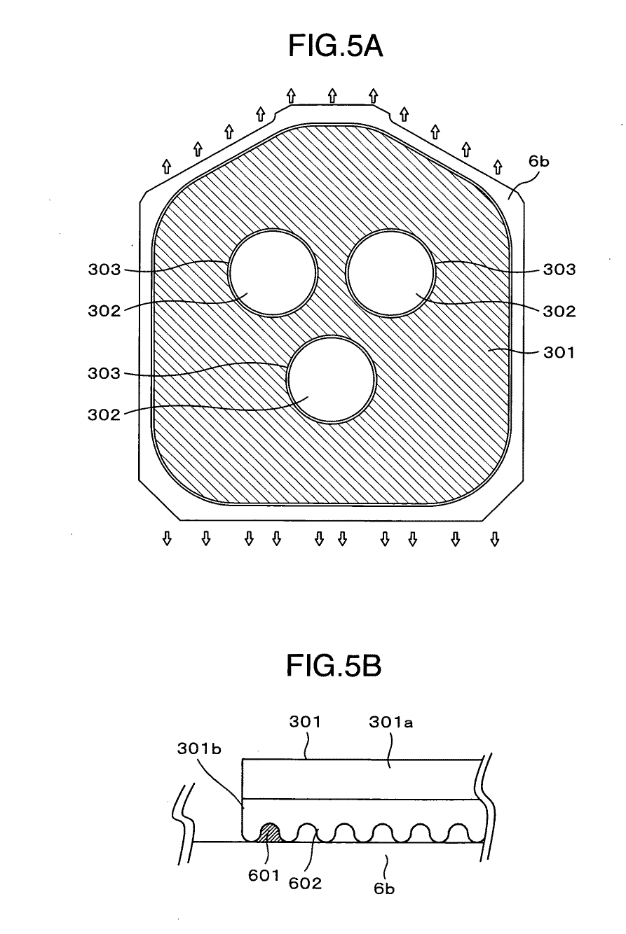

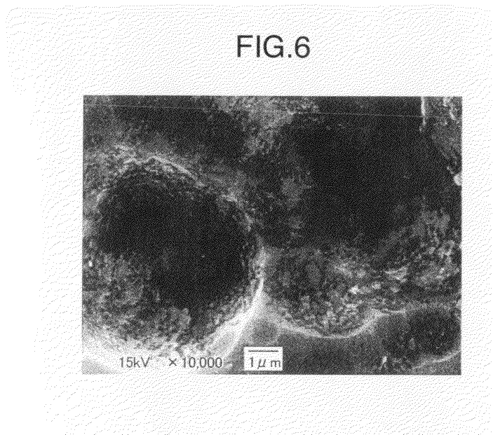

FIG. 5A shows another example of the film 301 bonded onto the lid 6b, and FIG. 5B shows a cross-sectional view of the film 301 of FIG. 5A.

A vertical section of the film 301 in FIG. 5B is illustrated with the upper side of the drawing being the side of the transfer chamber and the lower side of the drawing being the side of the lid 6b. As illustrated, the film 301 of this example, which is made of a material containing a resin as its main component as mentioned above, can be deformed with a elasticity, but the surface of the film to be bonded (upper or lower sides in the drawing) has a wave shape section having raised and recessed portions. Further such wave-shaped surface is elastic and also has a function of being bonded onto the surface of the lid 6b.

The surface of the film 301 to be bonded has recesses or grooves 601 arranged in a specific direction. In this example, these grooves are extended from one end of the film 301 to the other end thereof. When the film 301 having such a structure is bonded onto the rear surface (lower surface) of the lid 6b, raised portions 602 in the raised and recessed portions are first bonded.

Under such a condition, a plurality of lines of spaces in the grooves 601 are formed between the film 301 and the lid 6b, air or a gas in the atmosphere is present in these spaces. In this example, since the wave including raised and recessed portions as a combination of the grooves 601 and the raised portions 602 is arranged to be parallel to a specific direction, the spaces are arranged to be also parallel thereto. In particular, the shape of the film 301 and the wave direction of the raised and recessed portions may be arranged so that the grooves 601 are parallel to the longitudinal direction (for example, the longest direction of a distance between ends) of the lid 6b.

The film 301 of this example is made up of a plurality of film layers 301a, 301b in a vertical direction (film thickness direction). The layer 301b as the side of the film to be bonded onto the lid 6b has an elasticity lower than that of the upper layer 301a and can be largely deformed. The surface of the layer 301b has a high adhesive property. The upper layer 301a of the film facing the transfer chamber, on the other hand, has a higher stiffness, a higher plasma resistance and a larger strength. The plurality of layers are joined to each other upon manufacture of the film 301 to avoid generation of air bubbles or voids therein.

Further, the spaces are independently partitioned mutually by the raised portions 602 in the raised and recessed portions of the film 301 bonded onto the rear surface of the lid 6b. When a worker who bonds the film 301 collapses the spaces by depressing the film 301 toward the lid 6b from the surface of the film 301 opposed (upper side of the drawing) to the side of the grooves 601 formation to thereby tightly contact inner side faces of the grooves with the rear surface of the lid 6b; generation of air bubbles between the film 301 and the lid 6b, peel off of the film 301 or formation of foreign matter caused by air bubble generation can be suppressed.

In particular, the grooves 601 are extended as far as the end of the film 301 and communicate therewith, and when the worker tightly bonds and contacts both the film and lid each other by collapsing even an air bubble at the central part of the film 301 by pushing out the internal air bubble from the middle part of the groove 601 toward the lid (outer peripheral edge of the lid 6b), the air bubble can be excluded. In this example, further, the direction of the grooves 601 is set to be parallel to the to and fro direction of the vacuum processing apparatus 1 or to the longitudinal direction of the lid 6b, and the direction of the grooves 601 is the direction of pushing out and excluding the air bubble.

As mentioned above, the grooves 601 are formed to have a wave shaped surface having raised and recessed portions and to communicate with the both ends of the film 301. When the air bubble within the groove 601 is moved and pushed out finally from the opening of the end of the film 301, by pushing specific one point of the groove to get a tight contact between the lid 6b and the layer 301b and under this condition, by continuously pushing the groove toward one of the both ends. As a result, the recess of the groove 601 is collapsed along the bubble exclusion direction, and the surface of the film 301 having the groove 601 is tightly contacted with the lid 6b.

Such work as to remove the air bubble may be conducted as necessary not only when the film 301 is first bonded but also when the vacuum transfer vessel 6 is opened to the atmosphere for maintenance or the like after the film is bonded. The layer 301b is bonded onto the lid 6b with the layer having a low elasticity being largely deformed. And even when the lid 6b is deformed due to a difference between pressures at inside and outside the lid 6b, the layer 301b easily follows up a displacement in the surface.

In accordance with the foregoing embodiments, formation of foreign matter on the surface of a specimen transferred within the vacuum processing apparatus can be reduced to a large extent, and a semiconductor processing device can have a high processing reliability and productivity.

It should be further understood by those skilled in the art that although the foregoing description has been made on embodiments of the invention, the invention is not limited thereto and various changes and modifications may be made without departing from the spirit of the invention and the scope of the appended claims.

1. A vacuum processing apparatus comprising:
a vacuum vessel having a processing chamber provided therein into which a processing gas is supplied to form a plasma and which processes a wafer located in the processing chamber; and
a vacuum transfer vessel having a vacuumed transfer chamber coupled with the vacuum vessel provided therein into which the wafer is transferred;
wherein a resin-made film having a plasma resistance is bonded onto a surface of a lid of the vacuum transfer vessel on the side of the transfer chamber.

2. A vacuum processing apparatus according to claim 1, wherein the lid is a plate-like member is supported to be connected at its outer peripheral edge to a main body of the vacuum transfer vessel.

3. A vacuum processing apparatus according to claim 1 or 2, wherein the film is located on the surface of the lid at its central part on the side of the transfer chamber.

4. A vacuum processing apparatus according to claim 1, wherein the film is made of a resin containing polyimide or polyester as its main component.

5. A vacuum processing apparatus according to claim 1, wherein the lid is grounded and the film is conductive between the film and the lid.

6. A vacuum processing apparatus according to claim 1, wherein the film has a plurality of through holes which are passed between a surface of the film on the side of the transfer chamber and a bonding surface between the lid and the film and which are arranged at intervals of a predetermined spacing.

7. A vacuum processing apparatus according to claim 1, wherein the film has a plurality of grooves in the bonding surface which are extended from one end of the film to the other end thereof in a condition before the film is bonded onto the lid, and the groove formation surface is tightly contacted with the lid after the film is bonded.
